(19) United States
(12) Patent Application Publication
(10) Pub. No.: US 2014/0166049 A1
(43) Pub. Date: Jun. 19, 2014

(54) CLEANING METHOD OF PROCESS CHAMBER

(71) Applicant: JUSUNG ENGINEERING CO., LTD., Gwangju-si (KR)

(72) Inventors: SUNG-CHUL KANG, Seongnam-si (KR); BYOUNG-HA CHO, Seongnam-si (KR); JOO-YONG KIM, Seoul (KR)

(73) Assignee: JUSUNG ENGINEERING CO., LTD., Gwangju-si (KR)

(21) Appl. No.: 14/183,504

(22) Filed: Feb. 18, 2014

Related U.S. Application Data
(62) Division of application No. 12/947,992, filed on Nov. 17, 2010.

(30) Foreign Application Priority Data
Nov. 17, 2009 (KR) 10-2009-0110881

(51) Int. Cl. C23C 16/44

(52) U.S. Cl. CPC C23C 16/4405
USPC 134/19

(57) ABSTRACT

A cleaning method of a process chamber to remove a nitride layer including aluminum and a transition metal, which is adhered to an inner surface of the process chamber, includes removing the nitride layer by supplying cleaning gases to the process chamber, wherein the cleaning gases comprises a first gas including boron and a second gas including fluorine.

This application is a divisional of U.S. patent application Ser. No. 12/947,992, filed Nov. 17, 2010 which claims the benefit of Korean Patent Application No. 10-2009-0110881 filed on Nov. 17, 2009, which is hereby incorporated by reference.

### BACKGROUND OF THE INVENTION

1. Field of the Invention

The present invention relates to a cleaning method of a process chamber to which a nitride layer including aluminum and transition metal sticks.

2. Discussion of the Related Art

In general, a semiconductor device, a display device or a thin film solar cell is fabricated through a deposition process of depositing a thin film on a substrate, a photolithographic process of exposing or covering a selected area of the thin film using a photosensitive material, and an etching process of patterning the selected area of the thin film.

In a deposition process of forming a thin film including metal compounds on a substrate, a thin film of metal compounds is deposited on an inner surface of a process chamber simultaneously with depositing the thin film on the substrate. If the thin film is accumulated on the inner surface of the process chamber, the accumulated thin film may be peeled off, and minute particles may be dropped onto the substrate, thereby decreasing properties of the thin film deposited on the substrate. Accordingly, the process chamber should be cleaned cyclically to remove the thin film on the inner surface of the process chamber.

Meanwhile, in an etching process of etching a thin film by supplying an etching gas into a process chamber, by-products of the etched thin film may react with decomposition materials of the etching gas, and thus compounds, which are hard to be etched, may be generated. Especially, in case that the thin film is formed of a compound including aluminum and the etching gas includes fluorine, a compound of aluminum and fluorine, which are difficult to be etched, may be generated. The compound of aluminum and fluorine may remain on an inner surface of a process chamber and act as particles or impurities in a deposition process of forming a thin film on a substrate later, thereby decreasing properties of the thin film deposited on the substrate.

### SUMMARY OF THE INVENTION

Accordingly, the present invention is directed to a cleaning method of a process chamber that substantially obviates one or more of the problems due to limitations and disadvantages of the related art.

An advantage of the present invention is to provide a cleaning method of a process chamber, which a nitride layer including aluminum and transition metal sticks to, using a first gas including boron and a second gas including fluorine, to thereby remove the nitride layer including aluminum and a transition metal.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a cleaning method of a process chamber to remove a nitride layer including aluminum and a transition metal, which is adhered to an inner surface of the process chamber, includes removing the nitride layer by supplying cleaning gases to the process chamber, wherein the cleaning gases comprises a first gas including boron and a second gas including fluorine.

Here, the step of removing the nitride layer includes first step of increasing a temperature of an inside of the process chamber up to a predetermined temperature; second step of purging and exhausting the inside of the process chamber to be under vacuum; third step of supplying the first, second and third gases to the inside of the process chamber to remove the nitride layer; and fourth step of purging the process chamber.

In another aspect, a cleaning method of a process chamber to remove a nitride layer including aluminum and a transition metal, which is adhered to an inner surface of the process chamber, includes increasing a temperature of the process chamber up to a predetermined temperature; sequentially, repeatedly supplying first, second and third cleaning gases to an inside of the process chamber, thereby removing the nitride layer, wherein the first gas includes chlorine, the second gas includes boron, and the third gas includes fluorine; and purging the process chamber.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic view of illustrating a substrate treatment apparatus according to the present invention,

FIG. 2 is a view of illustrating an inner part of the substrate treatment apparatus according to the present invention,

FIG. 3 is a flow chart of a cleaning process according to a first embodiment of the present invention,

FIG. 4 is a picture of the inside of the process chamber that is cleaned using ClF₃,

FIG. 5 is a cross-sectional picture of a wafer that is cleaned using Cl₂,

FIG. 6 is a picture of a substrate holding unit in the process chamber that is completely cleaned,

FIG. 7 is a picture of a substrate holding unit in the process chamber that is cleaned using ClF₃ and Cl₂,

FIGS. 8A to 8D are cross-sectional views of illustrating steps in the cleaning process according to the first embodiment of the present invention,

FIG. 9 is a schematic view of a cleaning gas supply unit according to the first embodiment of the present invention,

FIGS. 10A and 10B are pictures of the inside of the process chamber that is cleaned Cl₂, BCl₃ and ClF₃ according to the first embodiment of the present invention,

FIG. 11 is a flow chart of a cleaning process according to a second embodiment of the present invention,

FIG. 12 is a schematic view of a cleaning gas supply unit according to the second embodiment of the present invention, and

FIGS. 13A to 13D are cross-sectional views of illustrating steps in the cleaning process according to the second embodiment of the present invention.

### DETAILED DESCRIPTION OF THE PREFERRED EMBODIMENTS

Reference will now be made in detail to the preferred exemplary embodiments, examples of which are illustrated in the accompanying drawings.

### First Embodiment

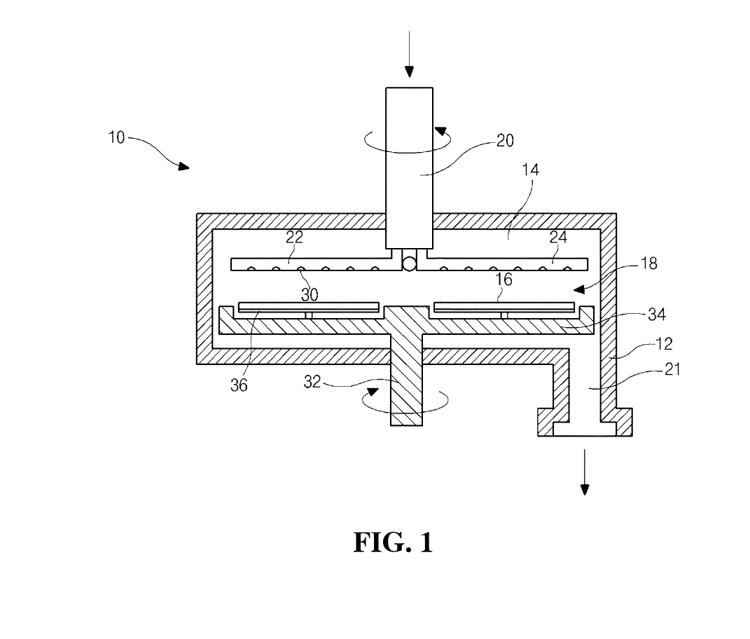

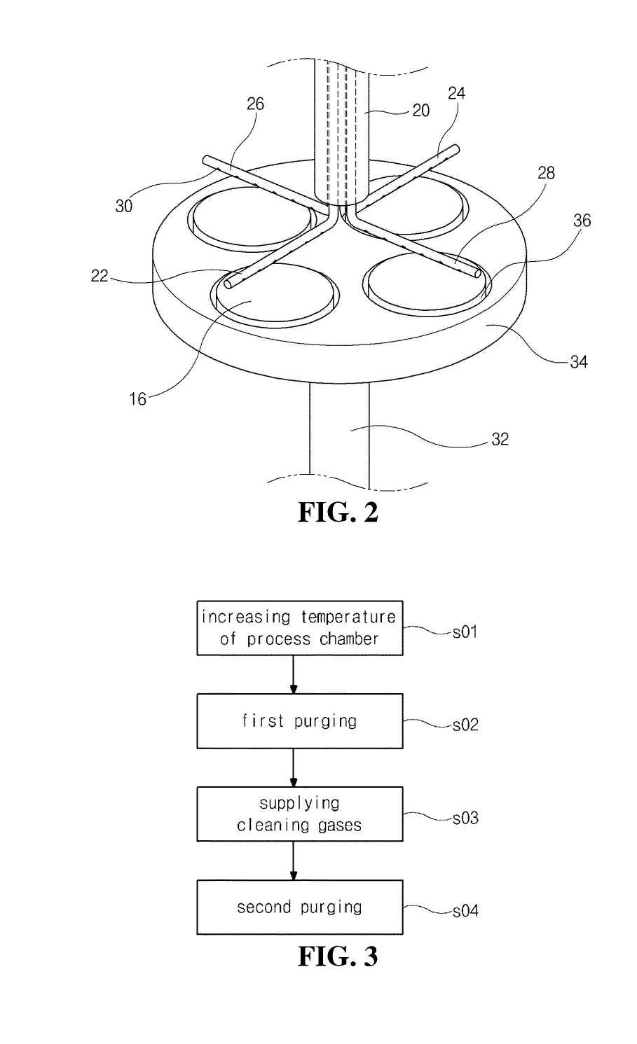

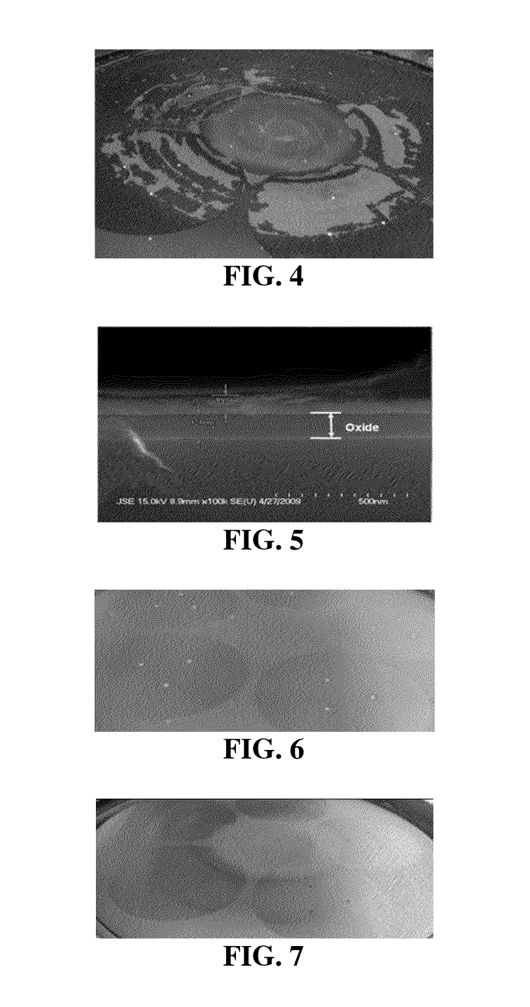

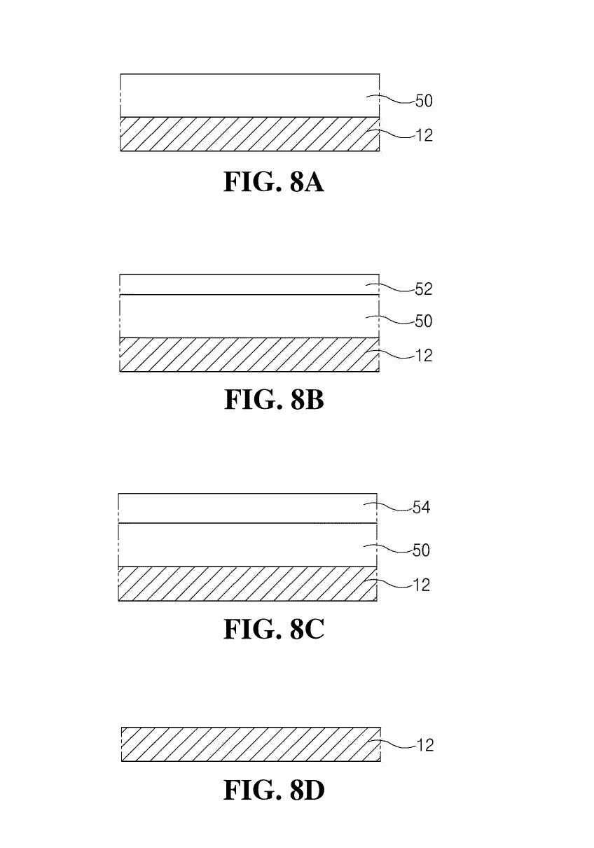

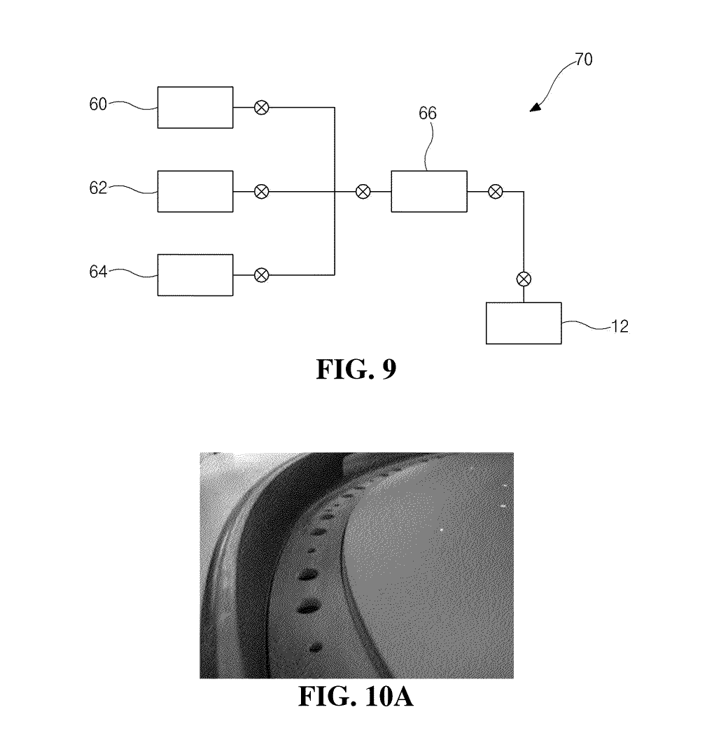

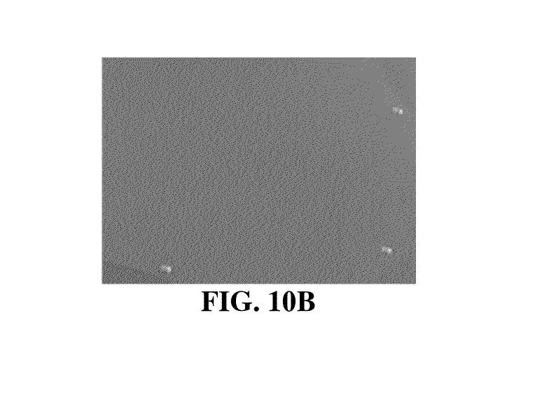

FIG. 1 is a schematic view of illustrating a substrate treatment apparatus according to the present invention, FIG. 2 is a view of illustrating an inner part of the substrate treatment apparatus according to the present invention, FIG. 3 is a flow chart of a cleaning process according to a first embodiment of the present invention, FIG. 4 is a picture of the inside of the process chamber that is cleaned using ClF₃, FIG. 5 is a cross-sectional picture of a wafer that is cleaned using Cl₂, FIG. 6 is a picture of a substrate holding unit in the process chamber that is completely cleaned, FIG. 7 is a picture of a substrate holding unit in the process chamber that is cleaned using ClF₃ and Cl₂, FIGS. 8A to 8D are cross-sectional views of illustrating steps in the cleaning process according to the first embodiment of the present invention, FIG. 9 is a schematic view of a cleaning gas supply unit according to the first embodiment of the present invention, and FIGS. 10A and 10B are pictures of the inside of the process chamber that is cleaned Cl₂, BCl₃ and ClF₃ according to the first embodiment of the present invention.

As illustrated in FIG. 1, the substrate treatment apparatus 10 for depositing a thin film includes a process chamber 12 providing a reaction region, a gas injection unit 14 set up inside the process chamber 12 and injecting source gases, reaction gases and purge gases, a substrate holding unit 18 set up under the gas injection unit 14 and holding substrates 16 thereon, a gas supply line 20 supplying the source gases, the reaction gases and the purge gases to the gas injection unit 14, and an outlet 21 exhausting gases in the reaction region.

The substrate holding unit 18 includes a shaft 32, a mail susceptor 34 and a plurality of sub-susceptors 36. The shaft 32 passes through a center of a bottom wall of the process chamber 12. The shaft 32 is connected to an exterior driving unit (not shown) and is movable upwards and downwards. The main susceptor 34 is connected to the shaft 32. The plurality of sub-susceptors 36 is set up onto the main susceptor 34, and the substrates 16 are disposed on respective sub-susceptors 36. In the substrate treatment apparatus 10 of FIG. 1, either the gas injection unit 14 or the substrate holding unit 18 may be rotated, or the gas injection unit 14 and the substrate holding unit 18 may be rotated in opposite directions or in the same direction.

The substrate holding unit 18 of FIG. 1 includes the shaft 32, the main susceptor 34 and the plurality of sub-susceptors 36, and if necessary, the substrate holding unit 18 may have different structures. For example, although not shown in the figure, one or more substrate-disposing regions for locating the substrates 16 are defined on the main susceptor 34, and a plurality of pins, which passes through the main susceptor 34 and is movable vertically upwards and downwards, is set up in each substrate-disposing region. Therefore, the substrates 16 may be disposed or carried out due to rise and fall of the plurality of pins.

As illustrated in FIG. 2, the gas injection unit 14 includes first, second, third and fourth gas injectors 22, 24, 26 and 28 to the gas supply line 20, which comprises a plurality of supply lines for supplying the source gases, the reaction gases and the purge gases. Each of the first, second, third and fourth gas injectors 22, 24, 26 and 28 has gas injection holes 30 for injecting the gases at a lower surface thereof. Even though four gas injectors are illustrated in FIG. 2, the number of gas injectors can be varied as occasion demands. For example, eight gas injectors may be set up. The first and third gas injectors 22 and 26 make an angle of 180 degrees with respect to each other. Each of the second and fourth gas injector 24 and 28 is disposed between the first and third gas injectors 22 and 26 and makes an angle of 90 degrees with respect to the first and third gas injectors 22 and 26. Each of the first, second, third and fourth gas injectors 22, 24, 26 and 28 is pipe-shaped.

The substrates 16 are disposed on the substrate holding unit 18 of FIG. 1, and the source gases, the reaction gases and the purge gases are injected through the first, second, third and fourth gas injectors 22, 24, 26 and 28. Then, the source gases, the purge gases, and the reaction gases are sequentially provided, and a thin film is formed on each substrate 16 due to rotation of the gas injection unit 14 or the substrate holding unit 18. Each of the first, second, third and fourth gas injectors 22, 24, 26 and 28 is connected to a purge gas supply line.

In the meantime, the source gases and the reaction gases may be provided through a showerhead and a gas supply line instead of the gas injection unit 14 including a plurality of gas injectors. The thin film formed on the substrate 16 may be a nitride layer including aluminum and a transition metal. For example, the nitride layer including aluminum and a transition metal may be TiAlN, and Ti may be replaced with another transition metal.

When a TiAlN layer is deposited as the nitride layer including aluminum and a transition metal by using the substrate treatment apparatus 10 of FIG. 1, a first source gas may include TiCl₄, which is a Ti precursor, a second source gas may include TMA (trimethylaluminum), which is an Al precursor, a reaction gas may include NH₃ having nitrogen, and a purge gas may include an inert gas such as Ar or a non reactive gas such as nitrogen.

The first source gas of TiCl₄ is injected through the first gas injector 22, the second source gas of TMA is injected through the second gas injector 24, the reaction gas of NH₃ is injected through the third and fourth gas injectors 26 and 28. Instead of TMA, the Al precursor may be selected from one of DMAH (dimethylaluminum hydride), TMEDA (tetramethylethylenediamine), DMEAA (dimethylehtylamine alane), TEA (triethylaluminum) and TBA (triisobutylaluminum).

The TiAlN layer is formed by an atomic layer deposition (ALD) method. More particularly, the TiAlN layer is formed by the following steps: at first step, the first source gas of TiCl₄ is injected on the substrate 16 through the first gas injector 22; at second step, the purge gas is injected through the first, second, third and fourth gas injectors 22, 24, 26 and 28; at third step, the reaction gas of NH₃ is injected through the third and fourth gas injectors 26 and 28; at fourth step, the purge gas is injected through the first, second, third and fourth gas injectors 22, 24, 26 and 28; at fifth step, the second source gas of TMA is injected through the second gas injector 24; at sixth step, the purge gas is injected through the first, second, third and fourth gas injectors 22, 24, 26 and 28; at seventh step, the reaction gas of NH₃ is injected through the third and fourth gas injectors 26 and 28; at eighth step, the purge gas is injected through the first, second, third and fourth gas injectors 22, 24, 26 and 28.

The first and second source gases, the reaction gas and reaction residues, which do not contribute to the reaction, are purged by the purge gas injected at the second, fourth, sixth and eighth steps. In the ALD method, the first to eighth steps constitute a cycle, and a thin film having a thickness of an atomic layer scale is formed through the cycle. To obtain a predetermined thickness, the cycle of the first to eighth steps is repeated several times to several hundred times. Accordingly, the TiAlN layer having a predetermined thickness is obtained by continuously repeating the first to eighth steps.

To increase productivity in the ALD method, as shown in FIG. 1 and FIG. 2, the plurality of substrates 16 are disposed on the substrate holding unit 18, more particularly, on the main susceptor 34, and the ALD process is performed to the substrates 16 at the same time. Alternatively, one substrate 16 may be disposed on the main susceptor 34, and the ALD process may be performed to the substrate 16. The former may be referred to as a batch type, and the latter may be referred to as a single type.

Here, even though the substrate treatment apparatus 10 of FIG. 1 is used for the ALD method to form the TiAlN layer, the substrate treatment apparatus 10 may be used for a physical vapor deposition (PVD) method applying physical collisions such as a sputtering method or a chemical vapor deposition (CVD) method applying chemical reaction.

When the thin film is formed on the substrate 16 by the sputtering method, the CVD method or the ALD method, a thin film of a transition metal material including aluminum is deposited on an inner surface of the process chamber 12. The thin film of the transition metal material including aluminum may be peeled off, and minute particles may be dropped onto the substrate 16, thereby decreasing the properties of the thin film deposited on the substrate 16. Accordingly, the process chamber 12 should be cleaned cyclically to remove the thin film deposited on the inner surface of the process chamber 12. The process chamber 12 may be cleaned when the thin film deposited on the inner surface of the process chamber 12 has a thickness of about 8 micrometers.

The thin film deposited on the inner surface of the process chamber 12 may be removed by supplying the process chamber 12 with ClF₃ including chlorine and fluorine as a cleaning gas after carrying the substrate 16 out of the process chamber 12. When the TiAlN layer is cleaned by ClF₃, aluminum, which is extracted from TiAlN, and fluorine, which is created by decomposition of ClF₃ are combined with each other, thereby generating an aluminum-fluorine (Al-F) compound such as AlF₃. The AlF₃ may be in a composition state by a complete bonding or incomplete reaction. The aluminum-fluorine compound, AlF₃, which is generated when the TiAlN layer deposited on the inner surface of the process chamber 12 is cleaned using the cleaning gas of ClF₃, is not removed and remains as porous white powers in the process chamber 12 as shown in FIG. 4.

Since the aluminum-fluorine compound remains at the inner surface of the process chamber 12, the aluminum-fluorine compound may be peeled off and particles may be dropped onto the substrate 16 in the following deposition process, thereby decreasing the properties of the thin film deposited on the substrate 16. The aluminum-fluorine compound is difficult to be decomposed by a general cleaning gas. Therefore, the aluminum-fluorine compound may be etched or removed by increasing a temperature of the inside of the process chamber 12 up to more than 1400 degrees of Celsius, weakening bonding strength of aluminum and fluorine, and increasing volatility. However, in a deposition apparatus for the ALD method such as the substrate treatment apparatus of FIG. 1, it is hard to increase the temperature of the inside of the process chamber 12 up to more than 1400 degrees of Celsius, and the aluminum-fluorine compound is substantially difficult to be removed.

Meanwhile, when the TiAlN layer deposited on the inner surface of the process chamber 12 is cleansed, Cl₂ may be used as the cleaning gas instead of ClF₃ so that the aluminum-fluorine compound may not be generated. However, in this case, an aluminum-chlorine (Al—Cl) compound such as AlCl₃ may be generated when the inside of the process chamber 12 is less than 430 degrees of Celsius. The AlCl₃ may be in a complete or incomplete bonding state. By the way, since it is difficult to maintain the whole inside of the process chamber under more than 430 degrees of Celsius, as shown in FIG. 5, the aluminum-chlorine compound partially exist.

FIG. 5 is a picture of a cross-section of a wafer, and to obtain results similar to the cross-section of the process chamber 12, the picture is taken after the wafer having a silicon oxide thereon is carried in the process chamber 12 and the TiAlN layer is deposited on the substrate 16. From FIG. 5, it is deduced that an aluminum-nitrogen compound exists in the process chamber 12.

When ClF₃ and Cl₂ are used as the cleaning gas, an etch rate of titanium-nitrogen (Ti—N) is higher than an etch rate of aluminum-nitrogen (Al—N) in the TiAlN layer, and the aluminum-nitrogen compound exists on the inner surface of the process chamber 12 after the cleaning process. The aluminum-nitrogen compound may remain on the inner surface of the process chamber 12 after the cleaning process is completed.

FIG. 6 is a picture of a substrate holding unit in a process chamber that is completely cleaned, and FIG. 7 is a picture of a substrate holding unit in a process chamber that is cleaned using ClF₃ and Cl₂. As compared with FIG. 6, FIG. 7 shows the aluminum-nitrogen compound remaining on the substrate holding unit in the process chamber.

To effectively clean the nitride layer including aluminum and a transition metal on the inner surface of the process chamber 12, the present invention suggests a cleaning method of a process chamber using a first cleaning gas and a second cleaning gas, wherein the first cleaning gas includes boron, which reacts with the nitride layer including aluminum and the transition metal and generates by-products having boron-nitrogen elements, and the second cleaning gas includes fluorine, which decomposes the by-products having boron-nitrogen elements to thereby exhaust them in gas phase.

With reference to FIG. 3, FIG. 8A to FIG. 8D and FIG. 9, a cleaning method of a process chamber according to the first embodiment of the present invention will be described hereinafter.

As shown in FIG. 3, the cleaning method of a process chamber includes: a first step SO1 of increasing a temperature of an inside of the process chamber 12 of FIG. 1; a second step SO2 of purging the inside of the process chamber 12 of FIG. 1 by supplying a first purge gas to the process chamber 12 of FIG. 1; a third step of removing the TiAlN layer 50 of FIG. 8A by supplying cleaning gases to the inside of the process chamber 12, and a fourth step SO4 of purging the inside of the process chamber 12 of FIG. 1 by supplying a second purge gas to the process chamber 12 of FIG. 1.

More particularly, after the TiAlN layer is deposited on the substrate 16 in the process chamber and the substrate 16 is carried out of the process chamber 12, the first step SO1 is performed, and the temperature of the inside of the process chamber 12 is increased up to a proper temperature for a cleaning process. As shown in FIG. 8A, the cleaning process may be performed when the TiAlN layer 50 is adhered to the inner surface of the process chamber 12 to have a thickness of about 8 micrometers. The time of the cleaning process can be appropriately adjusted. At the first step SO1, the temperature of the inside of the process chamber 12 may be increased up to 400 degrees of Celsius to 650 degrees of Celsius that is proper for the cleansing process. The increased temperature may vary depending on the cleaning gases. Additionally, a pressure of the inside of the process chamber 12 may be set up to 0.1 torr to 10 torr.

Since process gases for deposition of the TiAlN layer on the substrate 16 may remain in the gas supply line 20 and the process chamber 12, at the second step SO2, the inert gas such as argon (Ar), as the first purge gas, is provided to thereby remove the process gases in the gas supply line 20 and the process chamber 12. Therefore, there are no process gases due to the purge step, and the cleaning process is not affected by the process gases.

At the third step SO3, as shown in FIG. 8A, a first cleaning gas including boron and a second cleaning gas including fluorine are provided to remove the TiAlN layer 50 deposited on the inner surface of the process chamber 12.

The first cleaning gas, BCl₃, reacts with the TiAlN layer 50 of FIG. 8A as follows:

BCl₃+TiAlN->TiCl₄ (gas)+AlCl₃ (gas)+N₂ (gas)+BxNy (solid).

If the first cleaning gas is supplied to the inside of the process chamber 12 of FIG. 1, to which the TiAlN layer 50 is adhered, TiCl₄ generated by reaction of titanium (Ti) and chlorine (Cl), AlCl₃ generated by reaction of aluminum (Al) and chorine (Cl), and nitrogen decomposed from the TiAlN layer 50, which are in gas phase, may be exhausted to the outside through the outlet 21 of the process chamber 12, and a material including boron-nitrogen (B—N) elements is generated. Accordingly, an upper portion of the TiAlN layer 50 is decomposed by the first cleaning gas, and at the same time, as shown in FIG. 8B, a by-product 52 having the boron-nitrogen (B—N) elements is generated. The by-product 52 having the boron-nitrogen elements may be a compound or composition.

The second cleaning gas, ClF₃, reacts with the by-product 52 having the boron-nitrogen (B—N) elements of FIG. 8B as follows:

ClF₃+BxNy->BCl₃ (gas)+NF₃ (gas).

If the second cleaning gas is supplied to the inside of the process chamber 12 of FIG. 1, to which the TiAlN layer 50 is adhered, BCl₃ is generated by reaction of boron (B) and chlorine (Cl), and NF₃ is generated by reaction of nitrogen (N) and fluorine (F). Then, BCl₃ and NF₃ are exhausted to the outside through the outlet 21 of the process chamber 12.

Alternatively, the first and second cleaning gases may be simultaneously provided. Thus, the by-product 52 having the boron-nitrogen elements is generated by reaction of the first cleaning gas and a portion of the TiAlN layer 50 of FIG. 8A, and then the second cleaning gas decomposes the by-product 52 having the boron-nitrogen elements. These processes may be repeated, and as shown in FIG. 8D, the TiAlN layer 50 of FIG. 8A and FIG. 8B adhered to the inner surface of the process chamber 12 may be removed.

As shown in FIG. 8C, a third cleaning gas for generating an Al-rich TiAlN layer 54 may be supplied together with the first and second cleaning gases so that the by-product 52 having the boron-nitrogen elements may be easily generated by reaction with the TiAlN layer 50 of FIG. 8A.

Here, Cl₂ may be used as the third cleaning gas, and Cl₂ may react with the TiAlN layer 50 of FIG. 8A as follows:

Cl₂+TiAlN->TiCl₄ (gas)+AlCl₃ (gas)+N₂ (gas).

Then, TiCl₄ generated by reaction of titanium (Ti) and chlorine (Cl), AlCl₃ generated by reaction of aluminum and chlorine, and nitrogen decomposed from the TiAlN layer 50, which are in gas phase, are exhausted to the outside through the outlet 21 of the process chamber 12. Here, since an etch rate of titanium-nitrogen (Ti—N) is higher than an etch rate of aluminum-nitrogen (Al—N) in the TiAlN layer, as shown in FIG. 8C, an Al-rich TiAlN layer 54 is formed on the TiAlN layer 50. The Al-rich TiAlN layer 54 may react with the second cleaning gas to easily generate the by-product 52 having the boron-nitrogen elements.

The TiAlN layer 50 may be removed by repeatedly performing the processes of generating the Al-rich TiAlN layer 54 on the TiAlN layer 50 by the reaction of the third cleaning gas and the TiAlN layer 50 of FIG. 8A, generating the by-product 52 having the boron-nitrogen elements by the reaction of the second cleaning gas, the TiAlN layer 50 and the Al-rich TiAlN layer 54, and decomposing the by-product 52 having the boron-nitrogen elements by using the second cleaning gas. As shown in FIG. 8D, the TiAlN layer 50 can be completely removed due to mutual reaction of the first to third cleaning gases.

When the process chamber 12 is cleaned using Cl₂, BCl₃ and ClF₃ as the cleaning gases, as shown FIG. 10A and FIG. 10B, it is noted that by-products in the process chamber 12 are completely removed. Here, FIG. 10A is a picture of showing an inner surface of a process chamber and a portion at which an outlet is disposed, and FIG. 10B is a picture of showing a substrate holding unit in the process chamber.

The first to third cleaning gases can be simultaneously provided using a cleaning gas supply unit 70 as shown in FIG. 9. The cleaning gas supply unit 70 of FIG. 9 may include a first supply source 60 supplying the first cleaning gas, a second supply source 62 supplying the second cleaning gas, a third supply source 64 supplying the third cleaning gas, and a mass flow controller 66 between the first to third supply sources 60, 62 and 64 and the process chamber 12 for controlling flow rates of the first to third cleaning gases.

When the first to third cleaning gases are simultaneously provided to the process chamber 12 using the cleaning gas supply unit 70 of FIG. 9, the flow rates of the first, second and third cleaning gases, that is, BCl₃, ClF₃ and Cl₂, may be 1:0.6:2.

### Second Embodiment

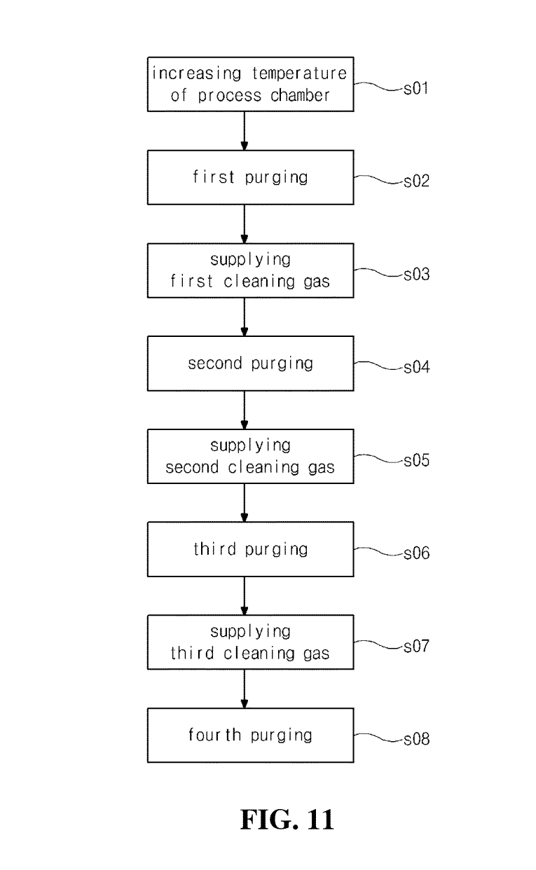

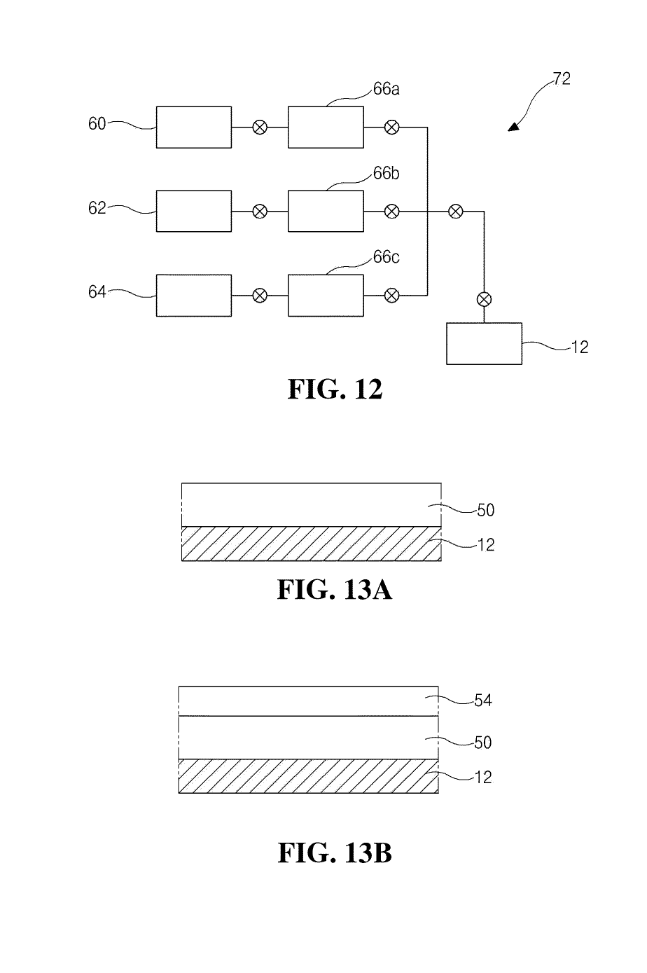

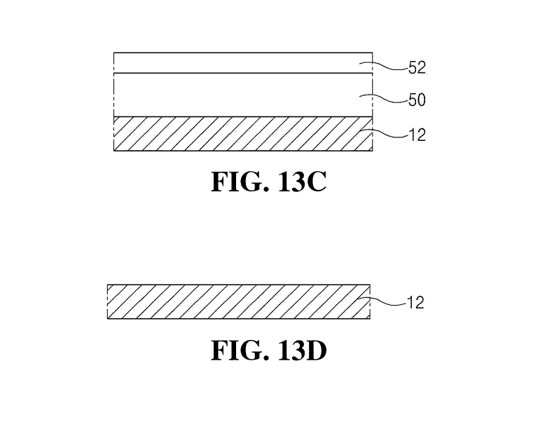

FIG. 11 is a flow chart of a cleaning process according to a second embodiment of the present invention, FIG. 12 is a schematic view of a cleaning gas supply unit according to the second embodiment of the present invention, and FIGS. 13A to 13D are cross-sectional views of illustrating steps in the cleaning process according to the second embodiment of the present invention. Here, the same references will be designated for the same parts as the first embodiment.

To effectively clean the nitride layer including aluminum and a transition metal on the inner surface of the process chamber, the second embodiment of the present invention suggests a cleaning method of a process chamber by sequentially repeatedly providing a first cleaning gas, a second cleaning gas and a third cleaning gas, wherein the first cleaning gas reacts with the nitride layer including aluminum and the transition metal and generates an Al-rich TiAlN layer, the second cleaning gas includes boron, which reacts with the TiAlN layer and the Al-rich TiAlN layer and generates by-products having boron-nitrogen elements, and the third cleaning gas includes fluorine, which decomposes the by-products having boron-nitrogen elements to thereby exhaust them in gas phase.

With reference to FIG. 11, FIG. 12 and FIG. 13A to FIG. 13D, a cleaning method of a process chamber according to the second embodiment of the present invention will be described hereinafter.

As shown in FIG. 11, the cleaning method of a process chamber for removing a TiAlN layer adhered to the inner surface of the process chamber includes: a first step SO1 of increasing a temperature of an inside of the process chamber 12 of FIG. 1; a second step SO2 of purging the inside of the process chamber 12 of FIG. 1 by supplying a first purge gas to the process chamber 12 of FIG. 1; a third step of supplying a first cleaning gas to the inside of the process chamber 12, a fourth step SO4 of purging the inside of the process chamber 12 of FIG. 1 by supplying a second purge gas to the process chamber 12 of FIG. 1, a fifth step SO5 of supplying a second cleaning gas to the inside of the process chamber 12, a sixth step SO6 of purging the inside of the process chamber 12 by supplying a third purge gas to the process chamber 12, a seventh step SO7 of supplying a third cleaning gas to the inside of the process chamber 12, and an eighth step SO8 of purging the inside of the process chamber 12 by supplying a fourth purge gas to the process chamber 12. The first to eighth steps are performed while the inside of the process chamber 12 is continuously kept under vacuum without breaking the vacuum state.

More particularly, after the TiAlN layer is deposited on the substrate 16 in the process chamber and the substrate 16 is carried out of the process chamber 12, the first step SO1 is performed, and the temperature of the inside of the process chamber 12 is increased up to a proper temperature for a cleaning process. As shown in FIG. 13A, the cleaning process may be performed when the TiAlN layer 50 is adhered to the inner surface of the process chamber 12 to have a thickness of about 8 micrometers. At the first step SO1, the temperature of the inside of the process chamber 12 may be increased up to 400 degrees of Celsius to 650 degrees of Celsius that is proper for the cleansing process. The increased temperature may vary depending on the cleaning gases.

Since process gases for deposition of the TiAlN layer on the substrate 16 may remain in the gas supply line 20 and the process chamber 12, at the second step SO2, the inert gas, as the first purge gas, is provided to thereby remove the process gases in the gas supply line 20 and the process chamber 12. Therefore, there are no process gases due to the purge step, and the cleaning process is not affected by the process gases.

At the third step SO3, Cl₂ may be used as the first cleaning gas, and Cl₂, reacts with the TiAlN layer 50 of FIG. 13A as follows:

Cl₂+TiAlN->TiCl₄ (gas)+AlCl₃ (gas)+N₂ (gas)

Then, TiCl₄ generated by reaction of titanium (Ti) and chlorine (Cl), AlCl₃ generated by reaction of aluminum and chlorine, and nitrogen decomposed from the TiAlN layer 50, which are in gas phase, are exhausted to the outside through the outlet 21 of the process chamber 12. Here, since an etch rate of titanium-nitrogen (Ti—N) is higher than an etch rate of aluminum-nitrogen (Al—N), as shown in FIG. 13B, a part of the TiAlN layer 50 becomes an Al-rich TiAlN layer 54.

At the fourth step SO4, an inert gas such as argon (Ar) is supplied as the second purge gas to completely exhaust the first cleaning gas in the gas supply line 20 and the process chamber 12 so that the cleaning process is not affected by mixing of the first cleaning gas remaining in the gas supply line 20 and the process chamber 12 and the second cleaning gas, which will be provided in the next step.

At the fifth step SO5, BCl₃ may be used as the second cleaning gas, and BCl₃ reacts with the TiAlN layer 50 of FIG. 13B as follows:

BCl₃+TiAlN->TiCl₄ (gas)+AlCl₃ (gas)+N₂ (gas)+BxNy (solid).

If the second cleaning gas is supplied to the inside of the process chamber 12 of FIG. 1, to which the TiAlN layer 50 is adhered, TiCl₄ generated by reaction of titanium (Ti) and chlorine (Cl), AlCl₃ generated by reaction of aluminum (Al) and chorine (Cl), and nitrogen decomposed from the TiAlN layer 50, which are in gas phase, may be exhausted to the outside through the outlet 21 of the process chamber 12, and a material including boron-nitrogen (B—N) elements is generated. Accordingly, an upper portion of the TiAlN layer 50 is decomposed by the second cleaning gas, and at the same time, as shown in FIG. 13C, a by-product 52 having the boron-nitrogen (B—N) elements is generated. The by-product 52 having the boron-nitrogen elements may be a compound or composition. Here, the Al-rich TiAlN layer 54 of FIG. 13B reacts with the second cleaning gas to easily generate the by-products 62 having the boron-nitrogen elements.

At the sixth step SO6, an inert gas such as argon (Ar) is supplied as the third purge gas to completely exhaust the second cleaning gas in the gas supply line 20 and the process chamber 12 so that the cleaning process is not affected by mixing of the second cleaning gas remaining in the gas supply line 20 and the process chamber 12 and the third cleaning gas, which will be provided in the next step.

At the seventh step SO7, the third cleaning gas, ClF₃, reacts with the by-product 52 having the boron-nitrogen (B—N) elements of FIG. 13C as follows:

ClF₃+BxNy->BCl₃ (gas)+NF₃ (gas).

If the third cleaning gas is supplied to the inside of the process chamber 12 of FIG. 1, to which the TiAlN layer 50 is adhered, BCl₃ is generated by reaction of boron (B) and chlorine (Cl), and NF₃ is generated by reaction of nitrogen (N) and fluorine (F). Then, BCl₃ and NF₃ are exhausted to the outside through the outlet 21 of the process chamber 12.

At the eighth step SO8, an inert gas such as argon (Ar) is supplied as the fourth purge gas to remove the third cleaning gas remaining in the gas supply line 20 and the process chamber 12, so that the third cleaning gas in the gas supply line 20 and the process chamber 12 is completely exhausted.

Accordingly, the TiAlN layer 50 adhered to the inner surface of the process chamber 12 may be removed by repeatedly performing the third to eighth steps. Here, if the first, second and third cleaning gases are provided to have the same flow rate at the third, fifth and seventh steps SO3, SO5 and SO7, respectively, amounts of the first, second and third cleaning gases depend on the supply time. When the first, second and third cleaning gases are provided to have the same flow rate, a ratio of the supply times of the first, second and third cleaning gases may be 2:1:0.6.

In the second embodiment of the present invention, to sequentially repeatedly provide the first, second and third cleaning gases, the cleaning gas supply unit 74, as shown in FIG. 12, may include a first supply source 60 supplying the first cleaning gas, a second supply source 62 supplying the second cleaning gas, a third supply source 64 supplying the third cleaning gas, and first, second and third mass flow controllers 66a, 66b and 66c between the first, second and third supply sources 60, 62 and 64 and the process chamber 12 for controlling the flow rates of the first to third cleaning gases, respectively.

It will be apparent to those skilled in the art that various modifications and variations can be made in the apparatus without departing from the spirit or scope of the invention. Thus, it is intended that the present invention covers the modifications and variations of this invention provided they come within the scope of the appended claims and their equivalents.

What is claimed is:

1. A cleaning method of a process chamber to remove a nitride layer including aluminum and a transition metal, which is adhered to an inner surface of the process chamber, comprising:
increasing a temperature of the process chamber up to a predetermined temperature;
sequentially, repeatedly supplying first, second and third cleaning gases to an inside of the process chamber, thereby removing the nitride layer, wherein the first cleaning gas includes chlorine, the second cleaning gas includes boron, and the third cleaning gas includes fluorine; and
purging the process chamber.

2. The cleaning method according to claim 1, wherein the nitride layer is a TiAlN layer, and the first, second and third cleaning gases are Cl₂, BCl₃, and ClF₃, respectively.

3. The cleaning method according to claim 2, further comprising:
first purging the inside of the process chamber by supplying a first purge gas between supplying the first cleaning gas and supplying the second cleaning gas;
second purging the inside of the process chamber by supplying a second purge gas between supplying the second cleaning gas and supplying the third cleaning gas; and
third purging the inside of the process chamber by supplying a third purge gas after supplying the third cleaning gas.

4. The cleaning method according to claim 2, wherein Cl₂ reacts the TiAlN layer to generate an Al-rich TiAlN layer, BCl₃ reacts with the TiAlN layer to generate a by-product having boron-nitrogen elements, and ClF₃ decomposes the by-product having boron-nitrogen elements.

5. The cleaning method according to claim 2, wherein the first, second and third cleaning gases are provided without breaking a vacuum state of the process chamber.

6. The cleaning method according to claim 2, wherein the first, second and third cleaning gases are provided to have the same flow rate, and a ratio of supply times of first, second and third cleaning gases is 2:1:0.6.

7. A cleaning method of a process chamber to remove a nitride layer including aluminum and a transition metal, which is adhered to an inner surface of the process chamber, comprising:
supplying a first cleaning gas including boron;
generating a by-product having boron-nitrogen elements by reaction of the first cleaning gas and the nitride layer;
supplying a second cleaning gas including fluorine; and
decomposing the by-product using the second cleaning gas.

8. The cleaning method according to claim 7, wherein steps of supplying the first cleaning gas, generating the by-product, supplying the second cleaning gas, and decomposing the by-product are sequentially repeated until the nitride layer is completely removed.

9. The cleaning method according to claim 7, wherein the nitride layer is a TiAlN layer, and the first and second cleaning gases are BCl₃ and ClF₃, respectively.

10. The cleaning method according to claim 9, wherein generating the by-product includes generating gas-phase TiCl₄, AlCl₃ and N₂ and solid-phase BxNy by reaction of the BCl₃ and the TiAlN layer.

11. The cleaning method according to claim 10, wherein decomposing the by-product includes generating gas-phase BCl₃ and NF₃ by reaction of the ClF₃ and the solid-phase BxNy.

12. The cleaning method according to claim 7, further comprising:
supplying a third cleaning gas including chlorine; and
generating an Al-rich nitride layer including aluminum and the transition metal from a part of the nitride layer using the third cleaning gas before supplying the first cleaning gas.

13. The cleaning method according to claim 12, further comprising generating a by-product having boron-nitrogen elements by reaction of the first cleaning gas and the Al-rich nitride layer between supplying the first cleaning gas and supplying the second cleaning gas.

14. The cleaning method according to claim 12, wherein the third cleaning gas is Cl₂.

15. The cleaning method according to claim 14, wherein generating the Al-rich nitride layer includes generating gas-phase TiCl₄, AlCl₃ and N₂ and generating an Al-rich TiAlN layer by reaction of the Cl₂ and the TiAlN layer.

16. The cleaning method according to claim 12, wherein the first, second and third cleaning gases are provided to have the same flow rate, and a ratio of supply times of first, second and third cleaning gases is 1:0.6:2.

17. The cleaning method according to claim 7, further comprising increasing a temperature of an inside of the process chamber up to a predetermined temperature before supplying the first cleaning gas.

18. The cleaning method according to claim 17, further comprising:
purging the inside of the process chamber using a first purge gas between increasing the temperature of the inside of the process chamber and supplying the first cleaning gas;
purging the inside of the process chamber using a second purge gas between generating the by-product and supplying the second cleaning gas; and
purging the inside of the process chamber using a third purge gas after decomposing the by-product.

19. The cleaning method according to claim 18, wherein the first, second, and third purge gases are inert gases including argon.
